(19) United States
(12) Patent Application Publication
(10) Pub. No.: US 2014/0254166 A1
(43) Pub. Date: Sep. 11, 2014

(54) LIGHT EMITTING DIODE LIGHTING AND METHOD OF MANUFACTURING LIGHTING

(71) Applicant: SAMSUNG ELECTRONICS CO., LTD., Suwon-si (KR)

(72) Inventor: Tetsuo ARIYOSHI, Suwon-si (KR)

(73) Assignee: SAMSUNG ELECTRONICS CO., LTD., Suwon-si (KR)

(21) Appl. No.: 13/974,726

(22) Filed: Aug. 23, 2013

(30) Foreign Application Priority Data
Mar. 11, 2013 (KR) 10-2013-0025524

(51) Int. Cl. F21K 99/00; H01L 33/58

(52) U.S. Cl. CPC F21K 9/50; H01L 33/58
USPC 362/293; 362/382; 362/311.02; 438/66

(57) ABSTRACT

The present application provides light emitting diode (LED) lighting including a white LED and a red LED. Chromaticity of the white LED has a color temperature of between about 2800 K to about 3700 K within a range according to ANSI C78. 377-2008 standard, and a range of the color temperature corresponds to a higher range than a chromaticity locus defined by blackbody radiation.

### CROSS-REFERENCE TO RELATED APPLICATION

This application claims the benefit of priority to Korean Patent Application No. 10-2013-0025524, filed on Mar. 11, 2013, in the Korean Intellectual Property Office, the disclosure of which is incorporated herein by reference.

### TECHNICAL FIELD

The present application relates to light emitting diode (LED) lighting and a method of manufacturing the LED lighting.

### BACKGROUND

Generally, light emitting diode (LED) lighting having high color reproduction characteristics has a high emission efficiency. Therefore, it is ideal to increase a high color rendering index (CRI), which is an index of the color reproduction characteristics, of the LED lighting.

A CRI of general LED lighting ranges between approximately 70 and 80. However, lighting used in places requiring high color reproduction characteristics, such as stores and shops, needs to have a CRI of about 90 or more. Therefore, halogen bulbs or incandescent bulbs, having a relatively lower emission efficiency than the LED lighting, are usually used for industrial lighting. Meanwhile, the industrial lighting may adopt LED lighting accomplishing the CRI of 90 or more. However, in this case, such industrial lighting may not be practically used since the structure becomes complicated and the price is increased.

LED lighting including a general white LED has a relatively low CRI of about 75 or lower, compared to an incandescent light source having a CRI of about 95 or more. The low CRI may be caused due to absence of light at a red part of a spectrum, where a wavelength is about 600 nm or more. A technology for integrating phosphor materials emitting red light has been developed to increase the CRI of the white LED. However, compared to yellow and green down converting phosphor materials, the phosphor materials emitting red light causes a great energy loss and a low efficiency of a light source.

General high-CRI LED lighting lacks red components having a wavelength of about 630 nm or more, which may cause a reduction in a CRI of LED lighting. To this end, LED lighting that achieves a CRI of about 90 or more is being developed, by combining a blue LED and a green LED phosphor material with a white LED and a red LED.

However, since the LED lighting controls current values of the white LED and the red LED using a feedback sensor, a circuit configuration may be complicated and a manufacturing cost may be increased.

### SUMMARY

According to an aspect of the present application, there is provided light emitting diode (LED) lighting including a white LED and a red LED, wherein chromaticity of the white LED may have a color temperature of between about 2800 K to about 3700 K within a range according to ANSI C78. 377-2008 standard, and a range of the color temperature may correspond to a higher range than a chromaticity locus defined by blackbody radiation.

A y-coordinate value of the chromaticity of the white LED is greater than an electrical locus.

According to an aspect of the present application, there is also provided LED lighting including a white LED, a red LED, and a diffusion plate, wherein chromaticity of the white LED has a color temperature of between about 3500 K to about 4800 K within a range according to ANSI C78. 377-2008 standard, and a lumen (lm) ratio of light radiated from the white LED and the red LED is defined by red LED:white LED=1:6˜red LED:white LED=1:14.

According to another aspect of the present application, there is provided a method of manufacturing LED lighting, the method including forming a substrate; forming at least one white LED on an upper surface of the substrate; and forming at least one red LED on the upper surface of the substrate, wherein chromaticity of the at least one white LED has a color temperature of between about 2800 K to about 3700 K within a range according to ANSI C78. 377-2008 standard, and a range of the color temperature corresponds to a higher range than a chromaticity locus defined by blackbody radiation.

According to another aspect of the present application, there is also provided a method of manufacturing LED lighting, the method including forming a substrate; forming at least one white LED on an upper surface of the substrate; forming at least one red LED on the upper surface of the substrate; and forming a diffusion plate at an upper portion of the at least one white LED and the at least one red LED, wherein chromaticity of the at least one white LED has a color temperature of between about 3500 K to about 4500 K within a range according to ANSI C78. 377-2008 standard, and a lumen (lm) ratio of light radiated from the at least one white LED and the at least one red LED is defined by red LED:white LED=1:6˜red LED:white LED=1:14.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

These and/or other aspects, features, and advantages of the application will become apparent and more readily appreciated from the following description of exemplary embodiments, taken in conjunction with the accompanying drawings of which:

FIG. 1 is a diagram illustrating an external structure of light emitting diode (LED) lighting according to an embodiment of the present application;

FIG. 2 is a diagram illustrating an internal structure of LED lighting according to an embodiment of the present application;

FIG. 3 is a graph illustrating a range of American National Standards Institute (ANSI) C78. 377-2008 standard;

FIG. 4 is a graph illustrating a result of measuring chromaticity of LED lighting according to an embodiment of the present application;

FIG. 5 is a diagram illustrating a range of chromaticity after a white LED and a red LED are mixed, according to an embodiment of the present application;

FIG. 6 is a side view illustrating a configuration of LED lighting according to an embodiment of the present application;

FIG. 7 is a side view illustrating a configuration of LED lighting according to another embodiment of the present application;

FIG. 8 is a diagram illustrating a result of calculating chromaticity of LED lighting according to an embodiment of the present application;

FIG. 9 is a graph illustrating a spectrum of LED lighting using a blue wavelength absorbent and a spectrum of LED lighting not using a blue wavelength absorbent, according to an embodiment of the present application;

FIG. 10 is a graph illustrating relative transmittance of a diffusion plate include in LED lighting, according to an embodiment of the present application;

FIG. 11 is a flowchart illustrating a manufacturing method of LED lighting, according to an embodiment of the present application;

### DETAILED DESCRIPTION

In the following detailed description, numerous specific details are set forth by way of embodiments in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Reference will now be made in detail to exemplary embodiments of the present application, examples of which are illustrated in the accompanying drawings but are not limited to the embodiments.

Terms to be used below are defined to properly explain the embodiments and may vary according to users, user's intentions, or practices. Therefore, the definitions of the terms should be determined based on the entire specification.

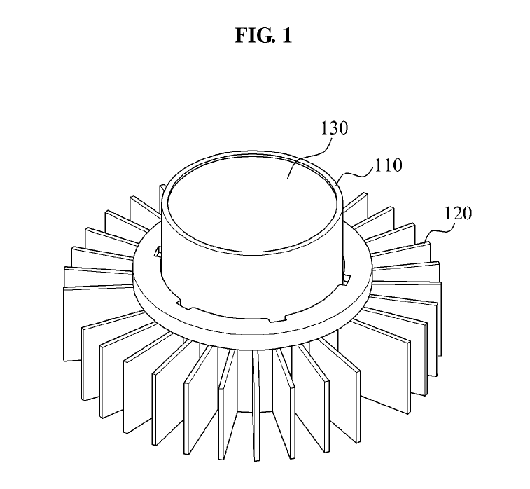

FIG. 1 is a diagram illustrating an external structure of light emitting diode (LED) lighting according to an embodiment of the present application.

Referring to FIG. 1, an appearance of the LED lighting includes a case 110 that may include a substrate to which a white LED and a red LED are mounted, a heat sink 120 adapted to absorb heat generated from a plurality of LEDs and emit the heat, and a diffusion plate 130 adapted to transmit and diffuse light generated from the plurality of LEDs.

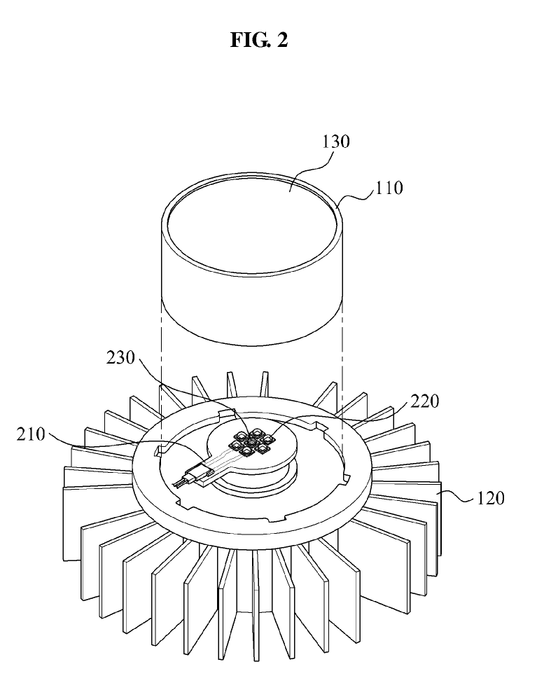

FIG. 2 is a diagram illustrating an internal structure of LED lighting according to an embodiment of the present application.

Referring to FIG. 2, a substrate 210 to which a white LED 220 and a red LED 230 are mounted may be formed by separating a case 110. In detail, for example, the LED lighting may include a power circuit, the substrate 210, six white LEDs 220, a single red LED 230, the case 110, a heat sink 120, and a diffusion plate 130. The white LEDs 220 and the red LED may be serially connected and supplied with a driving current from the power circuit.

The white LEDs 220 may adopt LEDs within a range of chromaticity defined by the American National Standards Institute (ANSI) C78. 377-2008 standard. This standard specifies the range of chromaticities recommended for general lighting with solid state lighting products, such as LED lighting, and ensures that the white light chromaticities of the products can be communicated to consumers. The standard applies to LED-based solid state lighting products with control electronics and heat sinks incorporated therein.

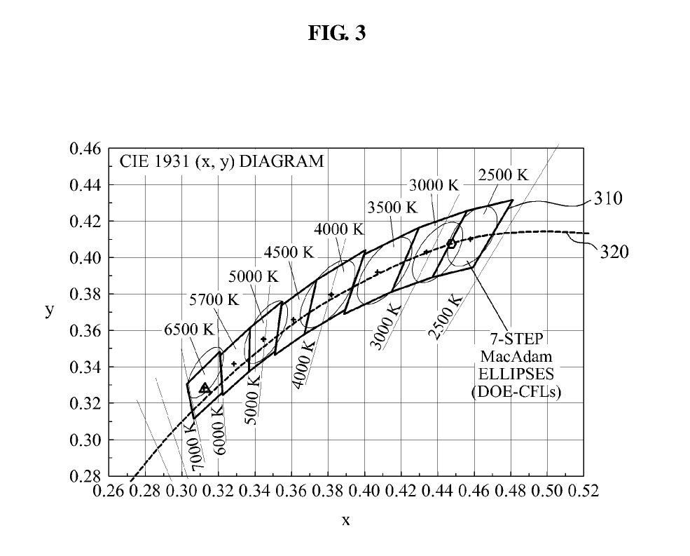

FIG. 3 is a graph illustrating a range 310 of ANSI C78. 377-2008 standard.

The range 310 of ANSI C78. 377-2008 standard may be determined according to chromaticity as shown in FIG. 3. A range 320 of blackbody radiation chromaticity may also to be defined by ANSI C78. 377-2008 standard. For example, in accordance with ANSI C78. 377-2008 standard, the range 310 may be expressed by outlines of eight rectangles on a blackbody locus of an LED. Accordingly, uniformity of the LED may be increased. In addition, ANSI C78. 377-2008 standard may be determined as single density and fine color binning according to a color binning system according to a color binning system.

The LED lighting may achieve high efficiency of a color temperature, a chromaticity, and a color rendering index (CRI), by adjusting an available chromaticity range and a ratio between the white LEDs and the red LED, for example, a ratio of lumen (lm) values or a ratio of a number of packages. For example, the chromaticity of the white LEDs 220 ranges from about 2800 K to about 3700 K within the range of ANSI C78. 377-2008 standard, which corresponds to a higher range than a chromaticity locus defined by the blackbody radiation. In the chromaticity of the white LEDs, a y-coordinate value may be greater than an electrical locus.

In the LED lighting, the lm ratio of light radiated from the white LEDs 220 and the red LED 230 may be defined by Equation 1.

red LED:white LED=1:6˜red LED:white LED=1:14 [Equation 1]

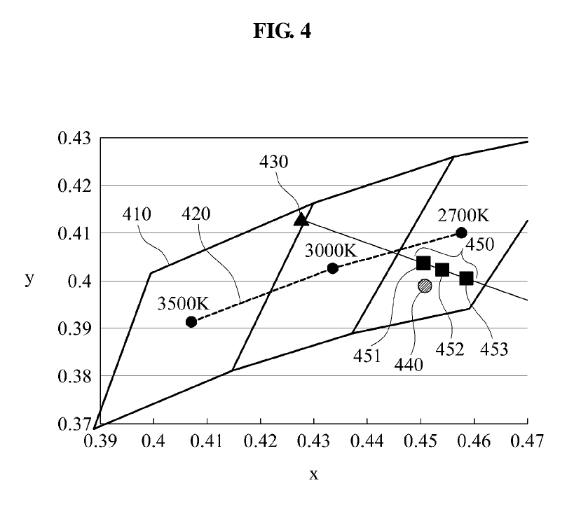

FIG. 4 is a graph illustrating a result of measuring chromaticity of LED lighting according to an embodiment of the present application.

The LED lighting may obtain a simulation result of chromaticity as shown by the graph of FIG. 4, by varying the ratio between the white LEDs and the red LED. Within a range 410 of ANSI C78. 377-2008 standard indicating blackbody radiation chromaticity curve 420, the LED lighting may obtain a measured chromaticity value 430 of the white LEDs, and a measured chromaticity value 440 of light formed by mixing the white LEDs and the red LED.

For example, when the ratio between the red LED and the white LEDs is 1:5, the to LED lighting may obtain a color temperature of about 2640 K and a CRI of about 94.2 as a simulation result value 450 according to the lm ratio between the red LED and the white LED, as indicated by 451. When the ratio is 1:6, the LED lighting may obtain a color temperature of about 2721 K and a CRI of about 92.7, as indicated by 452 in FIG. 4. When the ratio is 1:7, the LED lighting may obtain a color temperature of about 2783 K and a CRI of about 91.5, as indicated by 453. Here, the LED lighting is driven by a low current of about 350 mA. About 100 lm may be radiated from one white LED and about 60 lm may be radiated from the red LED. A peak wavelength of the red LED may range from about 600 nm to about 670 nm.

In the LED lighting including a white LED and a red LED, the chromaticity and the CRI may be varied according to a mixture ratio of light. For example, the chromaticity may be located on a straight line connecting chromaticity of the white LED and chromaticity of the red LED after colors are mixed. As red components are increased, the chromaticity after the color mixture may be approximated to chromaticity of the red LED. When the red components are insufficient, the CRI may not be satisfactorily increased. However, when the red components are excessive, the CRI may rather be decreased. Therefore, it is exemplary that the CRI of the LED lighting is about 90 or more and the chromaticity after the color mixture is within the range of the ANSI C78. 377-2008 standard.

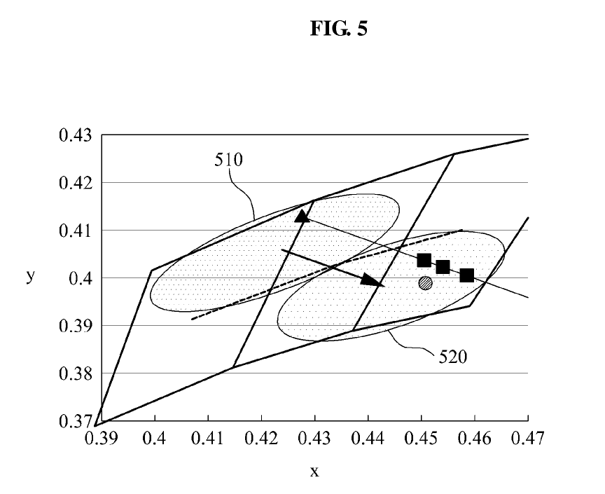

FIG. 5 is a diagram illustrating a range of chromaticity after a white LED and a red LED are mixed, according to an embodiment of the present application.

Referring to FIG. 5, a range 510 of chromaticity after the white LED and the red LED are mixed is within the range of ANSI C78. 377-2008 standard. For this purpose, chromaticity of the white LED of the LED lighting may be adjusted to be within a higher range 520 than a line defined by a color temperature from about 2800 K to about 3700 K and blackbody radiation within the range of ANSI C78. 377-2008 standard.

Also, a ratio of a number of packages between the white LEDs and the red LED may to be defined by Equation 2.

red LED:white LED=1:4˜red LED:white LED=1:8 [Equation 2]

For example, when the white LEDs and the red LED are driven in serial connection, the LED lighting ratio of the number of packages between the white LEDs and the red LED may be adjusted to between 1:4 and 1:8.

As another example, an lm ratio of light radiated from the white LEDs and the red LED may be adjusted to between 1:6 to 1:14.

Additionally, an available chromaticity range of the white LEDs may be increased by adding a material for absorbing a blue wavelength to an already manufactured diffusion plate or diffusion cover. Also, in this case, the manufacturing cost may be reduced. Since emission efficiency of the white LEDs of the LED lighting may be limited, the diffusion plate or diffusion cover may be added to relieve conditions for an available LED.

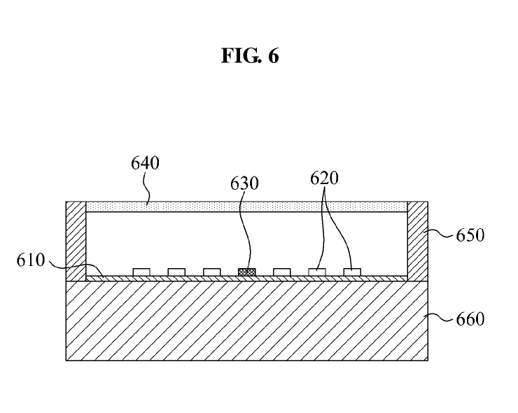

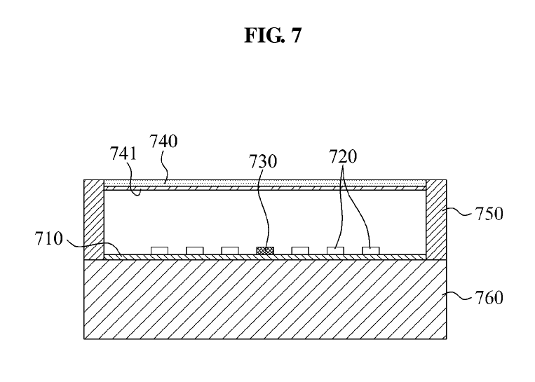

FIG. 6 is a side view illustrating a configuration of LED lighting according to an embodiment of the present application. FIG. 7 is side view illustrating a configuration of LED lighting according to another embodiment of the present application.

Referring to FIG. 6, the LED lighting may include a substrate 610, white lighting 620, red lighting 630, a diffusion plate 640, a case 650, and a heat sink 660. The diffusion plate 640 may include a material for absorbing a blue wavelength region.

Referring to FIG. 7, the LED lighting may include a substrate 710, white lighting 720, red lighting 730, a diffusion plate 740, a case 750, and a heat sink 760. An inside of the diffusion plate 740 may be coated with a blue wavelength absorbent. Alternatively, a film 741 including the blue wavelength absorbent may be attached to the inside of the diffusion plate 740. For example, the blue wavelength absorbent includes a resin material or a film that includes yellow colors used in a semiconductor plant and the like.

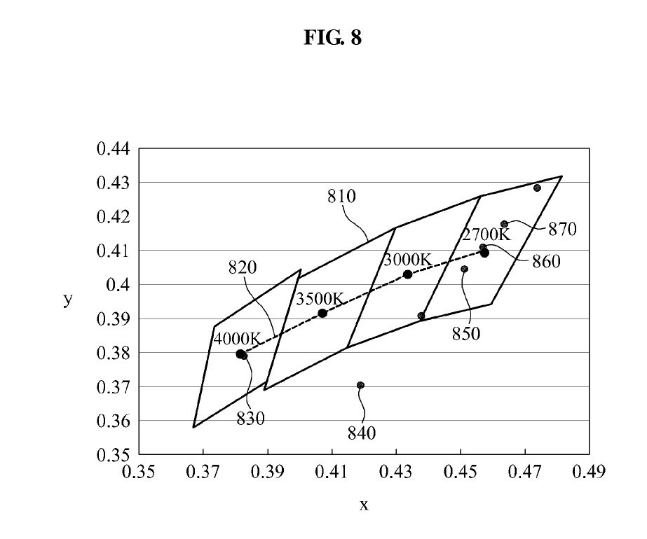

FIG. 8 is a diagram illustrating a result of calculating chromaticity of LED lighting according to an embodiment of the present application.

Referring to FIG. 8, when the LED lighting does not include a blue wavelength absorbent material, a chromaticity range 840 of the LED lighting may be beyond a range 810 of ANSI C78. 377-2008 standard including a blackbody radiation curve 820. However, when the blue wavelength absorbent is included, the chromaticity may be moved and the LED lighting may obtain chromaticity values 850, 860, and 870 which are within the range 810 of ANSI C78. 377-2008 standard.

Here, a coordinate 830 refers to chromaticity of a white LED. A coordinate 840 may obtain a chromaticity of LED lighting without a diffusion plate, in which a color temperature is about 3033 K and a CRI is about 92.8. A coordinate 850 may obtain a chromaticity of LED lighting with a diffusion plate, in which transmittance of a diffusion plate is about 60%, a color temperature is about 2778 K and a CRI of about 91.0. A coordinate 860 may obtain chromaticity of LED lighting with a diffusion plate, in which transmittance of a diffusion plate is about 53%, a color temperature is about 2740 K and a CRI is about 90.5. A coordinate 870 may obtain chromaticity of LED lighting with a diffusion plate, in which transmittance of a diffusion plate is about 46%, a color temperature is about 2703 K and a CRI is about 90.0.

Since the white LED of the LED lighting may be used around 4000 K within the range of ANSI C78. 377-2008 standard, the LED lighting may be used at a relatively low cost.

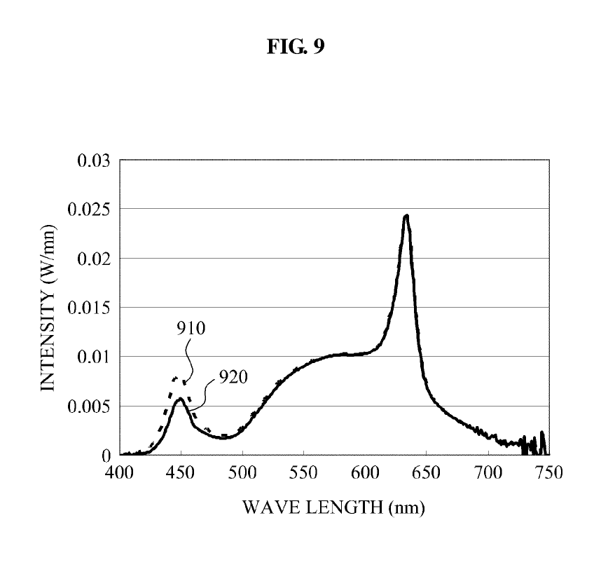

FIG. 9 is a graph illustrating a spectrum of LED lighting using a blue wavelength absorbent and a spectrum of LED lighting not using a blue wavelength absorbent, according to an embodiment of the present application

Referring to FIG. 9, a blue region of a case 920 in which the blue wavelength absorbent is used is less than a blue region of a case 910 in which the blue wavelength absorbent is used.

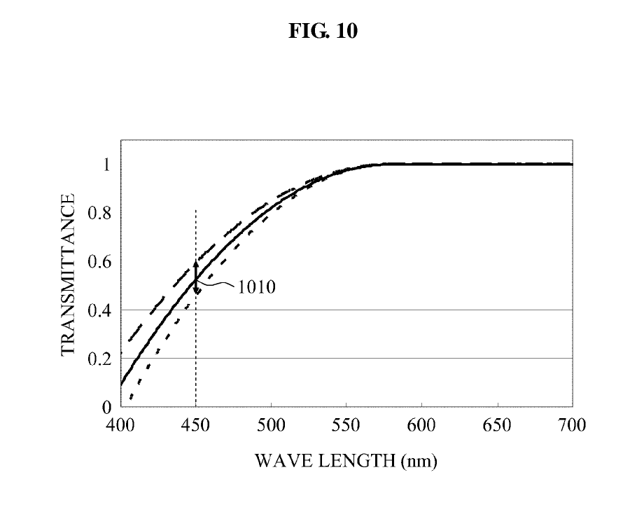

FIG. 10 is a graph illustrating relative transmittance of a diffusion plate include in to LED lighting, according to an embodiment of the present application.

Referring to FIG. 10, when a reference wavelength of the LED lighting is about 580 nm, transmittance at a peak wavelength, for example about 450 nm, of blue components of a white LED of the LED lighting may be within a range 1010 between about 40% to about 60%. In this case, color reproduction characteristics of the LED lighting may be increased by the diffusion plate including a red LED and a blue wavelength absorbent.

The LED lighting may include the white LED, the red LED, and the diffusion plate. Chromaticity of the white LED may have a color temperature of between about 3500 K to 4500 K within the range of ANSI C78. 377-2008 standard. An lm ratio of light radiated from the white LED and the red LED may be defined by Equation 3.

red LED:white LED=1:6˜red LED:white LED=1:14 [Equation 3]

Here, a wavelength of 580 nm is standardized as 100%, transmittance of the diffusion plate may be about 45% to about 60% with respect to a wavelength of 450 nm

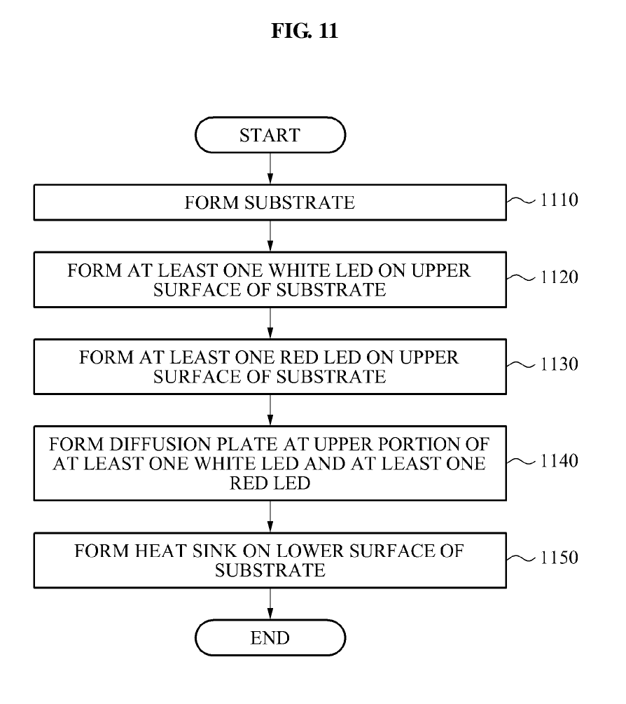

FIG. 11 is a flowchart illustrating a manufacturing method of LED lighting, according to an embodiment of the present application.

Referring to FIG. 11, in operation 1110, a substrate is formed according to the manufacturing method of LED lighting. In operation 1120, at least one white LED is formed on an upper surface of the substrate. In operation 1130, at least one red LED may be formed on the upper surface of the substrate, thereby manufacturing the LED lighting. Here, chromaticity of the at least one white LED may have a color temperature of between about 2800 K to 3700 K within the range of ANSI C78. 377-2008 standard, which corresponds to a higher range than a chromaticity locus defined by blackbody radiation.

An lm ratio of light radiated from the at least one white LED and the at least one red LED and a ratio of a number of packages may be referenced from the foregoing description and therefore will not be described again.

In operation 1140, a diffusion plate may be formed at an upper portion of the at least one white LED and the at least one red LED. In operation 1150, a heat sink may be provided at a lower surface of the substrate.

In addition, although the LED lighting may be manufactured by the foregoing manufacturing method, the color temperature of chromaticity of the white LED may be adjusted to from about 3500 K to about 4500 K within the range of ANSI C78. 377-2008 standard.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. Light emitting diode (LED) lighting comprising:
a white LED and a red LED, wherein:
chromaticity of the white LED has a color temperature of between about 2800 K to about 3700 K within a range according to ANSI C78. 377-2008 standard, and
a range of the color temperature corresponds to a higher range than a chromaticity locus defined by blackbody radiation.

2. The LED lighting of claim 1, wherein a y-coordinate value of the chromaticity of the white LED is greater than an electrical locus.

3. The LED lighting of claim 1, wherein a lumen (lm) ratio of light radiated from the white LED and the red LED is defined by Equation 1:
red LED:white LED=1:6˜red LED:white LED=1:14. [Equation 1]

4. The LED lighting of claim 1, wherein a ratio of a number of packages between the white LED and the red LED is defined by Equation 2:
red LED:white LED=1:4˜red LED:white LED=1:8. [Equation 2]

5. The LED lighting of claim 1, wherein a peak wavelength of the red LED ranges from about 600 nm to about 670 nm.

6. The LED lighting of claim 1, wherein a color rendering index (CRI) of the white LED and the red LED is 90 or more.

7. Light emitting diode (LED) lighting comprising:
a white LED;
a red LED; and
a diffusion plate, wherein:
chromaticity of the white LED has a color temperature of between about 3500 K to about 4800 K within a range according to ANSI C78. 377-2008 standard, and
a lumen (lm) ratio of light radiated from the white LED and the red LED is defined by Equation 3:
red LED:white LED=1:6˜red LED:white LED=1:14. [Equation 3]

8. The LED lighting of claim 7, wherein transmittance of the diffusion plate ranges from about 45% to about 60% with respect to a wavelength of 450 nm when a wavelength of 580 nm is standardized as 100%.

9. A method of manufacturing light emitting diode (LED) lighting, the method comprising steps of:
forming a substrate;
forming at least one white LED on an upper surface of the substrate; and
forming at least one red LED on the upper surface of the substrate, wherein:
chromaticity of the at least one white LED has a color temperature of between about 2800 K to about 3700 K within a range according to ANSI C78. 377-2008 standard, and
a range of the color temperature corresponds to a higher range than a chromaticity locus defined by blackbody radiation.

10. The method of claim 9, wherein a lumen (lm) ratio of light radiated from the at least one white LED and the at least one red LED is defined by Equation 4:
red LED:white LED=1:6˜red LED:white LED=1:14. [Equation 4]

11. The method of claim 9, wherein a ratio of a number of packages of the at least one white LED and the at least one red LED is defined by Equation 5:
red LED:white LED=1:4˜red LED:white LED=1:8. [Equation 5]

12. The method of claim 9, wherein a color rendering index (CRI) of the at least one white LED and the at least one red LED is 90 or more.

13. The method of claim 9, further comprising the step of:
disposing a diffusion plate at an upper portion of the at least one white LED and the at least one red LED.

14. The method of claim 13, wherein transmittance of the diffusion plate ranges from about 45% to about 60% with respect to a wavelength of 450 nm when a wavelength of 580 nm is standardized as 100%.

15. The method of claim 9, further comprising the step of:
forming a heat sink at a lower surface of the substrate.

16. A method of manufacturing light emitting diode (LED) lighting, the method comprising steps of:
forming a substrate;
forming at least one white LED on an upper surface of the substrate;
forming at least one red LED on the upper surface of the substrate; and
forming a diffusion plate at an upper portion of the at least one white LED and the at least one red LED, wherein:
chromaticity of the at least one white LED has a color temperature of between about 3500 K to about 4500 K within a range according to ANSI C78. 377-2008 standard, and
a lumen (lm) ratio of light radiated from the at least one white LED and the at least one red LED is defined by Equation 6:
red LED:white LED=1:6˜red LED:white LED=1:14. [Equation 6]

17. The method of claim 16, wherein transmittance of the diffusion plate ranges from about 45% to about 60% with respect to a wavelength of 450 nm when a wavelength of 580 nm is standardized as 100%.

18. The method of claim 16, further comprising the step of:
forming a heat sink at a lower surface of the substrate.

19. The LED lighting of claim 7, further comprising:
a cylindrical case encircling the substrate,
wherein the diffusion plate covers a hollow top surface of the cylindrical case.

20. The LED lighting of claim 19, wherein a blue wavelength absorbent is coated on the inside surface of the diffusion plate.
